(19) United States
(12) Patent Application Publication
(10) Pub. No.: US 2025/0344509 A1
(43) Pub. Date: Nov. 6, 2025

(54) ARRAY SUBSTRATE AND METHOD FOR PREPARING THE SAME, DISPLAY PANEL

(71) Applicant: HKC CORPORATION LIMITED, Shenzhen (CN)

(72) Inventors: Chuan Wu, Shenzhen (CN); Tianjun Huang, Shenzhen (CN); Haijiang Yuan, Shenzhen (CN)

(21) Appl. No.: 19/183,957

(22) Filed: Apr. 21, 2025

(30) Foreign Application Priority Data
May 6, 2024 (CN) 202410548824.6

(51) Int. Cl. H10D 86/40; H10D 86/01; H10D 86/60

(52) U.S. Cl. CPC H10D 86/443; H10D 86/0212; H10D 86/60

(57) ABSTRACT

The present application relates to the field of display panels, and provides an array substrate and a display panel. The array substrate includes a carrier substrate, a first signal line, a first insulating layer, a second signal line, a thin film transistor, a second insulating layer, and a discharge layer; the first insulating layer covers the first signal line and provides with a first through hole; the second signal line is located on a side of the first insulating layer away from the carrier substrate and connected with the first signal line through the first through hole; the second insulating layer covers the thin film transistor and the second signal line; the discharge layer is located on the surface of the second insulating layer and is connected to at least one of the first signal line and the second signal line.

### CROSS REFERENCE TO RELATED APPLICATION

Pursuant to 35 U.S.C. § 119 and the Paris Convention Treaty, the present application claims the benefit of Chinese Patent Application No. 202410548824.6 filed May 6, 2024, the contents of which are incorporated herein by reference.

### TECHNICAL FIELD

The present application relates to the field of display panels, and more specifically to an array substrate and a method for preparing the same, and a display panel.

### BACKGROUND

Thin Film Transistor Liquid Crystal Display (TFT-LCD) device has the advantages of good picture quality, small size, light weight, low driving voltage, low power consumption, no radiation and relatively low manufacturing cost, and occupies a dominant position in the display field.

The array substrate is an important part of a thin film transistor liquid crystal display device, which includes a carrier substrate and a circuit formed on a surface of the carrier substrate. The circuit structure on the surface of the array substrate is relatively fine, and the preparation process is relatively long. During the preparation process, some parts are prone to accumulate charges and eventually form electrostatic discharge, resulting in partial structural damage to the circuit and reducing the yield of the array substrate.

### SUMMARY

An embodiment of the present application provides an array substrate and a method for preparing the same, and a display panel; which can improve the yield of the array substrate.

A first aspect of an embodiment of the present application provides an array substrate, and the array substrate includes:
a carrier substrate, provided with a display area and a non-display area;
a first signal line, located in the non-display area;
a first insulating layer, covering at least the first signal line, and provided with a first through hole exposing the first signal line;
a second signal line, located on a side of the first insulating layer away from the carrier substrate and connected with the first signal line through the first through hole;
a thin film transistor, located in the display area, in which a gate of the thin film transistor is connected with the second signal line;
a second insulating layer, covering the thin film transistor and the second signal line; and
a discharge layer, located on a side of the second insulating layer away from the carrier substrate and connected with at least one of the first signal line and the second signal line.

In some examples, the first insulating layer is further provided with a second through hole exposing the first signal line, the second insulating layer is provided with a third through hole in communication with the second through hole, the discharge layer is connected with the first signal line through the second through hole and the third through hole, and the at least one through hole includes a fourth through hole located in the second through hole.

In some examples, the first insulating layer is further provided with a fourth through hole exposing the first signal line;
the array substrate further includes a transition conductive layer, in which the transition conductive layer is located on a side of the first insulating layer away from the carrier substrate, and is connected with the first signal line through the fourth through hole; and
the second insulating layer is provided with a fifth through hole exposing the transition conductive layer, and the first discharge layer is connected with the transition conductive layer through the fifth through hole.

In some examples, the transition conductive layer and the second signal line are arranged in a same layer and of a same material.

In some examples, the second insulating layer is provided with a sixth through hole exposing the second signal line, and the discharge layer is connected with the second signal line through the sixth through hole.

In some examples, the discharge layer is located outside the display area.

In some examples, the array substrate further includes a common electrode, in which the common electrode and the discharge layer are arranged in a same layer and of a same material.

In some examples, the second insulating layer is provided with a first insulating sub-layer and a second insulating sub-layer, the first insulating sub-layer covers the thin film transistor and the second signal line, the second insulating sub-layer is located at a side of the first insulating sub-layer away from the carrier substrate, and a material of the first insulating sub-layer is different from that of the second insulating sub-layer.

A second aspect of an embodiment of the present application provides a method for preparing an array substrate, and the preparing method includes:
forming a first signal line, a first insulating layer, a second signal line, and a thin film transistor on a surface of a carrier substrate; in which the carrier substrate is provided with a display area and a non-display area; the first signal line is located in the non-display area; the first insulating layer covers at least the first signal line, and is provided with a first through hole exposing the first signal line; the second signal line is located on a side of the first insulating layer away from the carrier substrate and connected with the first signal line through the first through hole; and the thin film transistor is located in the display area, wherein a gate of the thin film transistor is connected with the second signal line;
forming a second insulating layer; in which the second insulating layer covers the thin film transistor and the second signal line; and
forming a discharge layer located on a side of the second insulating layer away from the carrier substrate; in which the discharge layer is connected with at least one of the first signal line and the second signal line.

A third aspect of an embodiment of the present application provides a display panel, which includes a pairing substrate and an array substrate in the first aspect; in which the pairing substrate is arranged opposite to the array substrate.

In the first aspect of the embodiment of the present application, the first through hole exposing the first signal line is arranged on the first insulating layer, and the discharge layer is arranged while the second signal line is connected with the first signal line directly by the first through hole; the discharge layer is connected with at least one of the first signal line and the second signal line, this enables the charge accumulated at the first through hole to be released through one of the first signal line and the second signal line into the discharge layer during the preparation of the array substrate, which avoids further accumulation of charge at the first through hole and the possibility of electrostatic damage at the first through hole is reduced, and it is beneficial for improving the yield of the array substrate.

It is understandable that the beneficial effects of the second and third aspects mentioned above can be referred to the relevant descriptions in the first aspect above and will not be repeated here.

### BRIEF DESCRIPTION OF THE DRAWINGS

In order to explain the embodiments of the present application more clearly, a brief introduction regarding the accompanying drawings that need to be used for describing the embodiments of the present application or the prior art is given below; it is obvious that the accompanying drawings described as follows are only some embodiments of the present application, for those skilled in the art, other drawings can also be obtained according to the current drawings on the premise of paying no creative labor.

FIG. 1 is a top schematic diagram of an array substrate provided by an example of the present application;

FIG. 2 is a cross-section diagram of the array substrate in a non-display area as shown in FIG. 1;

FIG. 3 is a cross-section diagram of the array substrate in a display area as shown in FIG. 1;

FIG. 4 is a cross-section diagram of a second array substrate in a non-display area provided in Embodiment 2 of the present application;

FIG. 5 is a cross-section diagram of a second array substrate in a display area provided in Embodiment 2 of the present application;

FIG. 6 is a cross-section diagram of a non-display area of a third array substrate provided in Embodiment 3 of the present application;

FIG. 7 is a cross-section diagram of a non-display area of a fourth array substrate provided in Embodiment 4 of the present application;

FIG. 8 is a cross-section diagram of a non-display area of a fifth array substrate provided in Embodiment 5 of the present application;

FIG. 9 is a cross-section diagram of a display area of a sixth array substrate provided in Embodiment 6 of the present application; and

FIG. 10 is a flowchart of a method for preparing an array substrate provided in Embodiment 7 of the present application.

The reference numerals:

10—carrier substrate; 11—first signal line; 12—second signal line; 21—first insulating layer; 22—second insulating layer; 221—first insulating sub-layer; 222—second insulating sub-layer; 23—third insulating layer; 30—thin film transistor; 31—first electrode; 32—second electrode; 33—grid; 34—active layer; 40—discharge layer; 41—pixel electrode; 42—common electrode; 43—conductive protective layer; 10a—display area; 10b—non-display area; 21a—first through hole; 21b—second through hole; 22a—third through hole; 21c—fourth through hole; 22b—fifth through hole; 22c—sixth through hole; 221d—seventh through hole; 222d—eighth through hole; 221a—first sub-through hole; 222a—second sub-through hole; 221b—third sub-through hole; 222b—fourth sub-through hole; 221c—fifth sub-through hole; and 222c—sixth sub-through hole.

### DESCRIPTION OF THE EMBODIMENTS

In the following description, specific details such as specific system architecture, technology, etc. are presented for the purpose of illustration rather than qualification in order to fully understand the embodiment of the present application. However, it should be clear to those skilled in the art that the present application may also be realized in other embodiments without these specific details. In other cases, detailed descriptions of well-known systems, devices, circuits and methods are omitted so as not to prejudice the description of the present application with unnecessary details.

It is also understood that the term “and/or” as used in the description of the present application and the accompanying claims means any combination of one or more of the items listed in relation to them and all possible combinations thereof, and includes such combinations.

It is noted that when a component is referred to as being “fixed to” or “disposed on” another component, it can be directly or indirectly on another component. When a component is referred to as being “connected to” another component, it can be directly or indirectly connected with another component.

In the description of the present application, it needs to be understood that, directions or location relationships indicated by terms such as “length”, “width”, “up”, “down”, “front”, “rear”, “left”, “right”, “vertical”, “horizontal”, “top”, “bottom”, “inside”, “outside”, and so on are the directions or location relationships shown in the accompanying figures, which are only intended to describe the present application conveniently and simplify the description, but not to indicate or imply that an indicated device or component must have specific locations or be constructed and manipulated according to specific locations; therefore, these terms shouldn't be considered as any limitation to the present application.

In addition, the terms “first”, “second”, “third”, etc. in the description of the present application and the accompanying claims are used only to distinguish the description and are not to be construed as indicating or implying relative importance.

In the present application, references to “one embodiment” or “some embodiments” mean that specific features, structures, or characteristics described in connection with the embodiment are included in one or more embodiments of the present application. Therefore, the phrases “in one embodiment,” “in some embodiments,” “in other embodiments,” or “in additional embodiments” that appear in different parts of this description do not necessarily refer to the same embodiment, but rather to “one or more, but not all, embodiments,” unless otherwise specifically emphasized. The terms “comprises,” “includes,” “contains” and any of their variations are intended to cover non-exclusive inclusion, meaning “including but not limited to,” unless specifically emphasized otherwise. “Multiple” means two or more.

### Embodiment 1

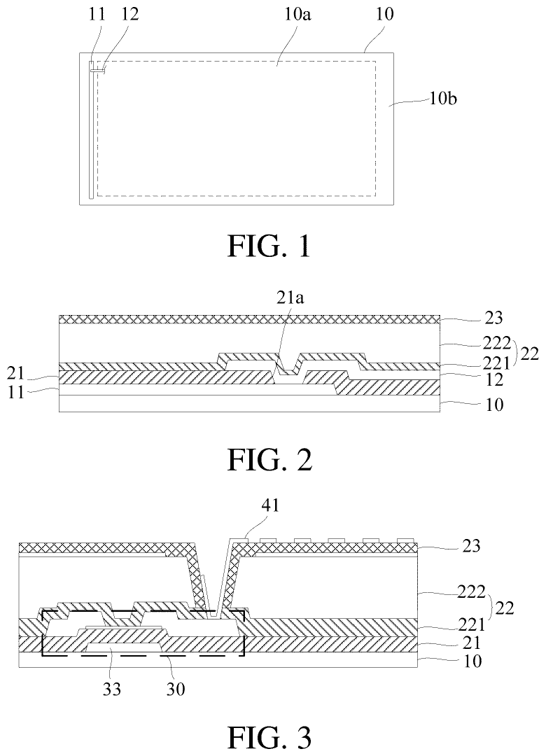

FIG. 1 is a top schematic diagram of an array substrate provided by an example of the present application. As shown in FIG. 1, the embodiment of the present application provides a first array substrate, the array substrate includes a carrier substrate 10 and a circuit formed on one side of the carrier substrate 10. The carrier substrate 10, as a carrier, is provided with a display area 10a and a non-display area 10b. The display area 10a is generally located in the middle of the carrier substrate 10, and the non-display area 10b is generally located at the edge of the carrier substrate 10. A first signal line 11 is provided in the non-display area 10b of the carrier substrate 10, and a second signal line 12 is provided in the display area 10a.

FIG. 2 is a cross-section diagram of the array substrate in a non-display area as shown in FIG. 1. As shown in FIG. 2, the side of the first signal line 11 away from the carrier substrate 10 is covered with the first insulating layer 21, and the second signal line 12 is located on the side of the first insulating layer 21 away from the carrier substrate 10. The second signal line 12 extends to display area 10a of the carrier substrate 10. The side of the second signal line 12 away from the carrier substrate 10 is further covered with a second insulating layer 22 and a third insulating layer 23 in turn. The second insulating layer 22 includes a first insulating sub-layer 221 and a second insulating sub-layer 222 that are laminated. The first insulating layer 21 is provided with a first through hole 21a, and the second signal line 12 and the first signal line 11 are connected through the first through hole 21a.

In embodiments of the present application, unless otherwise specified, connecting via through hole means achieving an electrical connection, the electrical connection is achieved by a structure located within the through hole. The structure used to achieve the electrical connection in the though hole can be a part of either of the two structures at either end of the though hole, or other structures other than the two structures at the two ends of the though hole. For example, the second signal line 12 and the first signal line 11 are connected through the first through hole 21a, which means that the two structures of the second signal line 12 and the first signal line 11 form an electrical connection. The structure of the first through hole 21a used to realize the electrical connection of the second signal line 12 and the first signal line 11 is the part of the second signal line 12 located in the first through hole 21a.

FIG. 3 is a cross-section diagram of the array substrate in a display area as shown in FIG. 1. As shown in FIG. 3, the thin film transistor 30 is distributed in the display area 10a. The gate 33 of the thin film transistor 30 is connected with the second signal line 12. The first insulating sub-layer 221 covers the thin film transistor 30, and a pixel electrode 41 is arranged on the side of the third insulating layer 23 away from the carrier substrate 10. The pixel electrode 41 is connected with one of the source and drain of the thin film transistor 30 through a through hole.

In the process of preparing the array substrate, if the etching at the first through hole 21a is not uniform, the appearance of the first through hole 21a is irregular, or there are burrs and foreign bodies left, a large amount of charge will accumulate at the first through hole 21a in the subsequent process. Charge accumulation may generate electrostatic discharge, which may cause the structure in or near the first through hole 21a to be burned by static electricity, resulting in damage to the array substrate, and reducing the yield of the array substrate.

### Embodiment 2

The embodiment of the present application provides a second array substrate, which includes a carrier substrate 10 and a circuit located on the surface of the carrier substrate 10.

After the array substrate is made into a display panel, the central area of the carrier substrate 10 corresponds to the area of the display screen, usually called the display area 10a, and the area outside the display area 10a is usually called the non-display area 10b, and the non-display area 10b is usually arranged around the display area 10a.

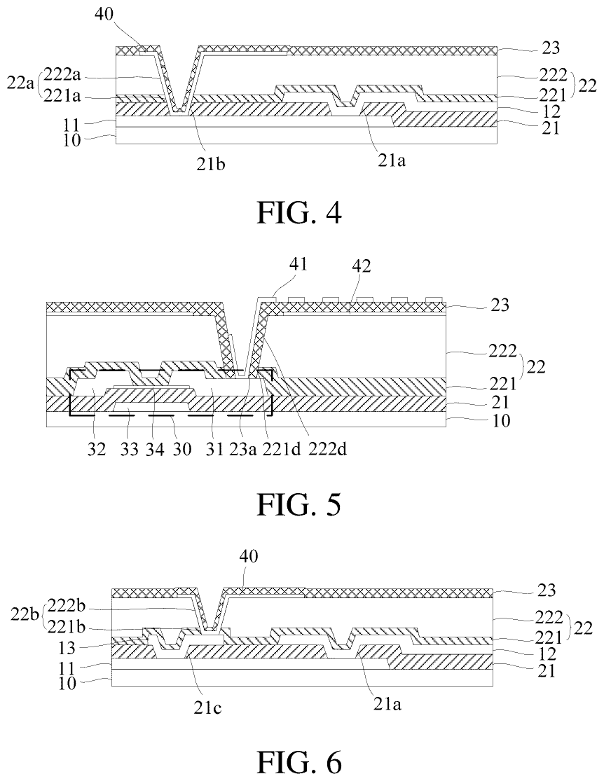

FIG. 4 is a cross-section diagram of a second array substrate in a non-display area provided in Embodiment 2 of the present application, and FIG. 5 is a cross-section diagram of a second array substrate in a display area provided in Embodiment 2 of the present application. As shown in FIGS. 4 and 5, the circuit in the array substrate include a first signal line 11, a first insulating layer 21, a second signal line 12, a thin film transistor 30, a second insulating layer 22, and a discharge layer 40.

The first signal line 11 is located in non-display area 10b. The first insulating layer 21 covers at least the first signal line 11, and the first insulating layer 21 is provided with a first through hole 21a exposing the first signal line 11. The second signal line 12 is located on the side of the first insulating layer 21 away from the carrier substrate 10, and the second signal line 12 is connected with the first signal line 11 through the first through hole 21a.

The discharge layer 40 is located on the side of the second insulating layer 22 away from the carrier substrate 10, and the discharge layer 40 is connected with at least one of the first signal line 11 and the second signal line 12.

As an example, in the embodiment shown in FIG. 4, the discharge layer 40 is connected with the first signal line 11.

As shown in FIG. 5, the thin film transistor 30 is located in display area 10a. The thin film transistor 30 is provided with a gate 33, a first electrode 31, and a second electrode 32, where the first electrode 31 is one of the source and drain, and the second electrode 32 is the other of the source and drain. The gate 33 of the thin film transistor 30 is connected with the second signal line 12. The second insulating layer 22 covers the thin film transistor 30 and the second signal line 12.

In the process of preparing the array substrate, the charge accumulated at the first through hole 21a can be directed into the discharge layer 40 through the first signal line 11 for release, which avoids further accumulation of charge at the first through hole 21a, thereby the possibility of electrostatic damage at the first through hole 21a is reduced, which is convenient to improve the yield of the array substrate.

The circuit on the surface of the carrier substrate 10 usually consists of a pixel circuit located in the display area 10a and a driver circuit located in the non-display area 10b. The driver circuit located in the non-display area 10b may for example, include a Gate Driver On Array (GOA) circuit. In the embodiment of the present application, the first signal line 11 can be a signal line in a gate drive circuit. The thin film transistor 30 can be a thin film transistor in a pixel circuit. The first signal line 11 is connected with the gate 33 of the thin film transistor 30 through the second signal line 12 to control the pixel circuit to operate.

As shown in FIG. 5, the array substrate further includes a common electrode 42, which is arranged in the same layer and is of the same material as the discharge layer 40.

Since the discharge layer 40 and the common electrode 42 are arranged in the same layer, and the materials are the same, that is, the discharge layer 40 and the common electrode 42 can be formed through the same composition process to achieve the purpose of saving the process.

As an example, the common electrode 42 and the discharge layer 40 can be all made of ITO material.

The first insulating layer 21 is further provided with a second through hole 21b exposing the first signal line 11, the second insulating layer 22 provides with a third through hole 22a in communication with the second through hole 21b, and the discharge layer 40 is connected with the first signal line 11 through the second through hole 21b and the third through hole 22a.

By providing the second through hole 21b and third through hole 22a that are in communication with each other, so that when the discharge layer 40 is prepared, a part of the discharge layer 40 can be directly formed in the second through hole 21b and the third through hole 22a and connected with the exposed area of the first signal line 11, which is simple in structure and short in the preparation process.

In some examples, the second insulating layer 22 can be a single layer structure.

In other examples, the second insulating layer 22 may also be a multi-layer structure.

For example, as shown in FIGS. 4 and 5, in embodiments of the present application, the second insulating layer 22 is a double layer structure including a first insulating sub-layer 221 and a second insulating sub-layer 222. The first insulating sub-layer 221 covers the thin film transistor 30 and the second signal line 12, and the second insulating sub-layer 222 is located on the side of the first insulating sub-layer 221 away from the carrier substrate 10. The material of the first insulating sub-layer 221 is different from that of the second insulating sub-layer 222.

In order to smooth the surface of the second insulating layer 22 away from the carrier substrate 10, so as to facilitate the subsequent formation of a common electrode 42, the thickness of the second insulating layer 22 is relatively thick. Because the greater the thickness of the second insulating layer 22, the deeper the depth of the need to be etched, the larger the thickness is not conducive to the production of the third through hole 22a. In the embodiment of the present application, the second insulating layer 22 is arranged into a multi-layer structure, so that each sub-layer can be processed by etching each other separately during preparing to reduce the depth of a single etching, so that the appearance of the third through hole 22a is more regular. In this example, the material of the first insulating sub-layer 221 is different from that of the second insulating sub-layer 222. When etching the second insulating sub-layer 222, an etching solution that is easy to etch the second insulating sub-layer 222 but not easy to etch the first insulating sub-layer 221 can be used to reduce the influence of the second insulating sub-layer 222 on the first insulating sub-layer 221. When etching the first insulating sub-layer 221, an etching solution that is easy to etch the first insulating sub-layer 221, but not easy to etch the second insulating sub-layer 222, can be used to reduce the influence of the first insulating sub-layer 221 on the second insulating sub-layer 222. When etching the first insulating sub-layer 221, the second insulating sub-layer 222 can also be used as a mask to simplify the process.

The first insulating sub-layer 221 can be located in the display area 10a and the non-display area 10b of the carrier substrate 10, covering the second signal line 12 and the thin film transistor 30. For example, the first insulating sub-layer 221 can be a passivation layer (PVX), and the first insulating sub-layer 221 can be made of an inorganic non-metallic material, for example, the first insulating sub-layer 221 may include at least one of the silicon nitride layer and the silicon oxide layer. The first insulating sub-layer 221 includes, by example, a SiOₓ layer and a SiNₓ layer laminated on the side of the SiOₓ layer away from the carrier substrate 10.

As shown in FIG. 4, the third through hole 22a includes the first sub-through hole 221a located on the first insulating sub-layer 221 and the second sub-through hole 222a located on the second insulating sub-layer 222, and the first sub-through hole 221a, the second sub-through hole 222a and the second through hole 21b are in communication with each other.

As shown in FIG. 5, the first insulating sub-layer 221 is provided with a seventh through hole 221d exposing the first electrode 31 of the thin film transistor 30. The second insulating sub-layer 222 can be located in the display area 10a and the non-display area 10b of the carrier substrate 10, and the second insulating sub-layer 222 covers on the side of the first insulating sub-layer 221 away from the carrier substrate 10.

The second insulating sub-layer 222 can be made of inorganic non-metallic materials, for example, the second insulating sub-layer 222 can be a resin layer, a photoresist layer, or an acrylic layer. For example, the second insulating sub-layer 222 can be a perfluoroalkoxy resin PFA.

Optionally, the thickness of the second insulating sub-layer 222 is 1.5 μm to 3 μm. The thickness of the second insulating sub-layer 222 is arranged relatively thick to form a relatively flat surface, so that the subsequent film layer is relatively flat.

The second insulating sub-layer 222 is provided with an eighth through hole 222d in communication with the seventh through hole 221d. The array substrate further includes a third insulating layer 23 and a pixel electrode 41, the third insulating layer 23 is located on the side of the second insulating sub-layer 222 away from the carrier substrate 10 and is partially located in the seventh through hole 221d. The third insulating layer 23 is further provided with a ninth through hole 23a exposing the first electrode 31 of the thin film transistor 30. The pixel electrode 41 is located on the side of the third insulating layer 23 away from the carrier substrate 10, and the pixel electrode 41 is connected with the first electrode 31 of the thin film transistor 30 through the ninth through hole 23a.

The third insulating layer 23 is partially located in the seventh through hole 221d, which means that the seventh through hole 221d is formed before the formation of the third insulating layer 23, and the seventh through hole 221d and the ninth through hole 23a are prepared separately and are not in the same etching process, which avoids the problem of poor shape of through hole and difficult process caused by too large single etching depth, and it is conducive to improving the yield of the array substrate.

A part of the pixel electrode 41 is located on the surface of the third insulating layer 23 away from the carrier substrate 10, and the other part is located in the seventh through hole 221d, the eighth through hole 222d and the ninth through hole 23a, so as to form an electrical connection with the first electrode 31 of the thin film transistor 30.

As an example, the pixel electrode 41 can be made of ITO (Indium tin oxide) material. The third insulating layer 23 can be made of SiNₓ material.

As shown in FIG. 4, the discharge layer 40 is located outside the display area 10a.

The pixel electrode 41 is usually located in the display area 10a and works in conjunction with the common electrode 42. When the array substrate is working, a certain electric field will be generated between the discharge layer 40 and the pixel electrode 41. The discharge layer 40 is placed outside the display area 10a, the distance between the discharge layer 40 and the pixel electrode 41 located near the edge of the display area 10a can be increased, thus the influence of the electric field between the discharge layer 40 and the pixel electrode 41 on the display screen can be reduced.

As an example, the first signal line 11 is arranged in the same layer as the gate 33 of the thin film transistor 30 and is of the same material. Since the discharge layer 40 and the gate 33 of the thin film transistor 30 are arranged in the same layer, and the materials are the same, that is, the first signal line 11 and the gate 33 of the thin film transistor 30 can be formed through the same composition process to achieve the purpose of saving the process. For example, the first signal line 11 can be a single layer structure made of metal materials, such as a single layer structure formed by metal copper Cu, or a multi-layer structure made of metal materials, such as Al/Mo/MTD material, that is, a multi-layer structure of aluminum layer, molybdenum layer, molybdenum nickel-titanium layer.

The first insulating layer 21 can be located in the display area 10a and the non-display area 10b. For example, the first insulating layer 21 can be a gate insulating layer. The first insulating layer 21 can be made of an inorganic non-metallic material, for example, the first insulating layer 21 can include at least one of a silicon nitride layer and a silicon oxide layer. The first insulating layer 21 includes, for example, a SiNₓ layer and a Si_{Ox} layer laminated on one side of the SiNₓ layer away from the carrier substrate 10.

The active layer 34 of the thin film transistor 30 is located on the side of the first insulating layer 21 away from the carrier substrate 10. For example, the thin film transistor 30 can be an oxide thin film transistor, and the active layer 34 can be a metal oxide semiconductor layer. In some examples, a thin film transistor 30 can also be a polycrystalline silicon thin film transistor, an amorphous silicon thin film transistor, or other thin film transistors.

The first electrode 31 and the second electrode 32 of the thin film transistor 30 are located on the side of the first insulating layer 21 away from the carrier substrate 10. At least two of the first electrode 31, the second electrode 32 and the second signal line 12 of the thin film transistor 30 can be arranged in the same layer and are of the same material. For example, in the embodiment of the present application, the first electrode 31, the second electrode 32 and the second signal line 12 of the thin film transistor 30 are arranged in the same layer and are of the same material, that is, the first electrode 31, the second electrode 32 and the second signal line 12 of the thin film transistor 30 can be formed by the same composition process to achieve the purpose of saving the process. For example, the second signal line 12 can be a single layer structure made of metal materials, such as a single layer structure formed by copper Cu, or a multi-layer structure made of metal materials, such as Al/Mo/MTD material, that is, a multi-layer structure of aluminum layer, molybdenum layer, molybdenum nickel-titanium layer.

The first insulating layer 21 can further provide with a through hole in the display area 10a through which the second signal line 12 is connected with the gate of the thin film transistor 30. For example, a gate line can also be arranged in the display area 10a, and the gate line is connected with the gate 33 of the thin film transistor 30, and the second signal line 12 is connected with the gate line through the through hole to realize the electrical connection between the second signal line 12 and the gate 33 of the thin film transistor 30.

### Embodiment 3

The embodiment of the present application provides a third array substrate, and FIG. 6 is a cross-section diagram of the non-display area of a third array substrate provided in Embodiment 3 of the present application. As shown in FIG. 6, in the array substrate, the first insulating layer 21 is provided with a fourth through hole 21c exposing the first signal line 11. The array substrate also includes a transition conductive layer 13, which is located on the side of the first insulating layer 21 away from the carrier substrate 10, and the transition conductive layer 13 is connected with the first signal line 11 through the fourth through hole 21c. The second insulating layer 22 is provided with a fifth through hole 22b exposing the transition conductive layer 13, and the discharge layer 40 is connected with the transition conductive layer 13 through the fifth through hole 22b.

The total thickness of the first insulating layer 21 and the second insulating layer 22 is relatively thick, and the total depth of the through hole penetrating through the first insulating layer 21 and the through hole penetrating through the second insulating layer 22 is relatively large, which makes it difficult for the discharge layer 40 to attach to the hole wall of the through hole when preparing the discharge layer 40. Even if the discharge layer 40 is attached to the hole wall of the through hole, this part is prone to fracture. In the embodiment of the present application, a transitional conductive layer 13 is arranged on the surface of the first insulating layer 21 away from the carrier substrate 10, so that the discharge layer 40 does not need to be attached to the hole wall of the fifth through hole 21c, which reduces the difficulty of preparing the discharge layer 40 and also reduces the possibility of fracture of the part of the discharge layer 40 located in the through hole.

As shown in FIG. 6, the fifth through hole 22b includes the third sub-through hole 221b located on the first insulating sub-layer 221 and the fourth sub-through hole 222b located on the second insulating sub-layer 222. The third sub-through hole 221b and the fourth sub-through hole 222b are in communication with each other, and the third sub-through hole 221b is staggered with the fifth through hole 21c. The discharge layer 40 can be connected with the relatively flat surface of the transition conductive layer 13.

As an example, the transition conductive layer 13 is arranged in the same layer and made of the same material as the second signal line 12.

Since the transition conductive layer 13 and the second signal line 12 are arranged in the same layer, and the materials are the same, that is, the transition conductive layer 13 and the second signal line 12 can be formed through the same composition process to achieve the purpose of saving the process. For example, the first signal line 11 can be a single layer structure made of metal material, such as a single layer structure formed by metal copper Cu, or a multi-layer structure made of metal materials, such as Al/Mo/MTD material, that is, a multi-layer structure of aluminum layer, molybdenum layer, and molybdenum nickel-titanium layer.

### Embodiment 4

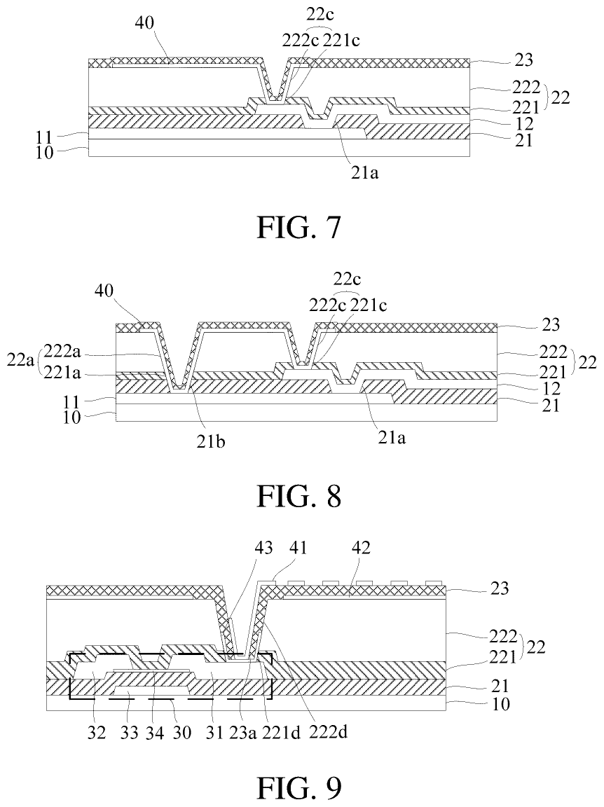

The embodiment of the present application provides a fourth array substrate, and FIG. 7 is a cross-section diagram of a non-display area of a fourth array substrate provided in Embodiment 4 of the present application. As shown in FIG. 7, in the array substrate, the second insulating layer 22 is provided with a sixth through hole 22c exposing the second signal line 12, and the discharge layer 40 is connected with the second signal line 12 through the sixth through hole 22c.

In this example, the sixth through hole 22c includes a fifth sub-through hole 221c located on the first insulating sub-layer 221 and a sixth sub-through hole 222c located on the second insulating sub-layer 222, and the fifth sub-through hole 221c and the sixth sub-through hole 222c are in communication with each other.

By arranging the sixth through hole 22c connecting the discharge layer 40 with the second signal line 12, the charge accumulated near the first through hole 21a can pass through the second signal line 12 and be directed to the discharge layer 40 through the sixth through hole 22c.

The structure of the display area 10a in the array substrate can be the same as in the other embodiments mentioned above, which will not be described here.

### Embodiment 5

The embodiment of the present application provides a fifth array substrate, and FIG. 8 is a cross-section diagram of a non-display area of a fifth array substrate provided in Embodiment 5 of the present application. As shown in FIG. 8, in the array substrate, the discharge layer 40 is connected with both the first signal line 11 and the second signal line 12.

As shown in FIG. 8, in the array substrate, the first insulating layer 21 is provided with a second through hole 21b exposing the first signal line 11, the second insulating layer 22 is provided with a third through hole 22a in communication with the second through hole 21b and a sixth through hole 22c exposing the second signal line 12. The discharge layer 40 is connected with the first signal line 11 through the second through hole 21b and the third through hole 22a; and the discharge layer 40 is connected with the second signal line 12 through the sixth through hole 22c.

The charge accumulated near the first through hole 21a can pass through the second signal line 12 and direct to the discharge layer 40 via the through hole, and can pass through the first signal line 11 and direct to the discharge layer 40 via the through hole. If the discharge layer 40 is connected with the through hole of the first signal line 11, and the discharge layer 40 is connected with the through hole of the second signal line 12, even if there is an anomaly in one of them, for example, the through hole connecting the discharge layer 40 and the first signal line 11 is broken due to technological reasons, the charge can be directed to the discharge layer 40 through the other through hole, the reliability is improved.

In the example shown in FIG. 8, the discharge layer 40 and the first signal line 11 can also be connected through the transition conductive layer 13, and the structure setting can refer to the example shown in FIG. 6, which will not be repeated here. The structure of the display area 10a in the array substrate can refer to other embodiments mentioned above and will not be described here.

### Embodiment 6

The embodiment of the present application provides a sixth array substrate, and FIG. 9 is a cross-section diagram of a display area of a sixth array substrate provided in Embodiment 6 of the present application. As shown in FIG. 9, compared with the array substrate shown in FIG. 5, the array substrate also includes a conductive protective layer 43 in the display area 10a that is mutually insulated with a common electrode 42. The common electrode 42 and the conductive protective layer 43 are located between the second insulating sub-layer 222 and the third insulating layer 23. The conductive protective layer 43 is located at least in the seventh through hole 221d and covers the first electrode 31 of the thin film transistor 30.

The conductive protective layer 43 can be used to protect the first electrode 31 of the thin film transistor 30. Taking dry etching as an example, when etching in a process that the conductive material is used to prepare a common electrode 42, the conductive materials in the seventh through hole 221d and the eighth through hole 222d are etched away, and the first electrode 31 of the thin film transistor 30 will be exposed and bombarded by ions. By forming the conductive protective layer 43, the first electrode 31 of the thin film transistor 30 can be protected to avoid damage to the first electrode 31 of the thin film transistor 30.

In the embodiment of the present application, the conductive protective layer 43 and the common electrode 42 are arranged in the same layer and of the same material, for example, both can be made of ITO material. That is, the conductive protective layer 43 and the common electrode 42 can be formed through the same composition process to achieve the purpose of saving the process. In this case, when the conductive material is etched to form a conductive protective layer 43 and the common electrode 42, masks are provided on the side of the conductive protective layer 43 away from the carrier substrate 10 and the side of the common electrode 42 away from the carrier substrate 10. The mask on the side of the conductive protective layer 43 away from the carrier substrate 10 plays a protective role, which avoids etching of the conductive protective layer 43 and the first electrode 31 of the thin film transistor 30.

In some examples, the conductive protective layer 43 can also be formed before the common electrode 42, so that the first electrode 31 of the thin film transistor 30 will not be affected when the common electrode 42 is prepared.

As shown in FIG. 9, the conductive protective layer 43 covers the hole wall of the seventh through hole 221d and part of the hole wall of the eighth through hole 222d.

The conductive protective layer 43 blocks the first electrode 31 of the thin film transistor 30 to provide protection. By arranging the area of the conductive protective layer 43 to be larger to cover the hole wall of the eighth through hole 222d, the shielding range of the conductive protective layer 43 can be increased, so as to avoid damage to the first electrode 31 of the thin film transistor 30 because the conductive protective layer 43 does not completely block the bottom of the seventh through hole 221d due to errors and other reasons.

In the embodiment of the present application, the conductive protective layer 43 covers part of the hole wall of the eighth through hole 222d, and in other examples, the conductive protective layer 43 can cover all of the hole wall of the eighth through hole 222d, and can even cover part area of the surface of the second insulating sub-layer 222 away from the carrier substrate 10.

The third insulating layer 23 can cover the surface of the second insulating layer 222 away from the carrier substrate 10, and cover the hole wall of the eighth through hole 222d, and the surface of the conductive protective layer 43 away from the carrier substrate 10.

The pixel electrode 41 is located on the side of the third insulating layer 23 away from the carrier substrate 10, and is partially located in the ninth through hole 23a. The conductive protective layer 43 is connected with the pixel electrode 41 to the first electrode 31 of the thin film transistor 30.

Since the conductive protective layer 43 is conductive, after the pixel electrode 41 is prepared, the pixel electrode 41 can form an electrical connection with the first electrode 31 of the thin film transistor 30 through the conductive protective layer 43.

The structure of the non-display area 10b on the array substrate can be referred to the other embodiments mentioned above and will not be described here.

### Embodiment 7

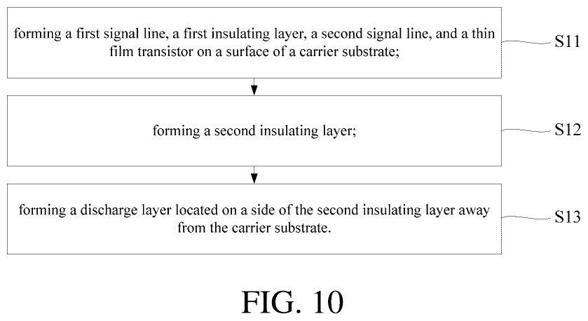

FIG. 10 is a flowchart of a method for preparing an array substrate provided in Embodiment 7 of the present application. The method can be used to prepare any of the array substrates shown in FIGS. 4-9. As shown in FIG. 10, the method includes steps as following:

In a step S11, a first signal line 11, a first insulating layer 21, a second signal line 12, and a thin film transistor 30 are formed on the surface of the carrier substrate 10.

The carrier substrate 10 is provided with a display area 10a and a non-display area 10b, the first signal line 11 is located in the non-display area 10b, the first insulating layer 21 covers at least the first signal line 11, and the first insulating layer 21 is provided with a first through hole 21a exposing the first signal line 11. The second signal line 12 is located on the side of the first insulating layer 21 away from the carrier substrate 10, and the second signal line 12 is connected with the first signal line 11 through the first through hole 21a. The thin film transistor 30 is located in the display area 10a, and the gate 33 of the thin film transistor 30 is connected with the second signal line 12.

In a step S12, a second insulating layer 22 is formed.

The second insulating layer 22 covers the thin film transistor 30 and the second signal line 12.

In a step S13, a discharge layer 40 is formed on the side of the second insulating layer 22 away from the carrier substrate 10.

The discharge layer 40 is connected with at least one of the first signal line 11 and the second signal line 12.

In the process of preparing the array substrate, the charge accumulated at the first through hole 21a can be directed into the discharge layer 40 through the first signal line 11 for release, which avoids further accumulation of charge at the first through hole 21a, thereby the possibility of electrostatic damage at the first through hole 21a is reduced, which is convenient to improve the yield of the array substrate.

### Embodiment 8

Embodiments 8 of the present application provide a display panel, which can be, but not limited to, a display panel in a mobile phone, a tablet computer, a laptop computer, a monitor, a smart wearable device, or a vehicle mounted display device. The display panel includes a pairing substrate and an array substrate, which can be any of the array substrates shown in the preceding embodiment.

### Embodiment 9

Embodiments 9 of the present application provide a display device including the display panel of the above-mentioned embodiments. The display device can be, but is not limited to, a mobile phone, a tablet computer, a laptop computer, a monitor, a smart wearable device, or a vehicle mounted display device.

The above embodiments are used only to illustrate the technical solution of the present application and not to restrict the present application. Notwithstanding the detailed description of the present application by reference to the foregoing embodiments, it should be understood by those skill in the art that they may modify the technical scheme recorded in the foregoing embodiments or make equivalent substitutions for some of the technical features; such modification or replacement shall not separate the essence of the corresponding technical scheme from the scope of the technical scheme of each embodiment of the present application, and shall be included in the scope of protection of the present application.

What is claimed is:

1. An array substrate, comprising:
a carrier substrate, provided with a display area and a non-display area;
a first signal line, located in the non-display area;
a first insulating layer, covering at least the first signal line, and providing with a first through hole exposing the first signal line;
a second signal line, located on a side of the first insulating layer away from the carrier substrate and connected with the first signal line through the first through hole;
a thin film transistor, located in the display area, wherein a gate of the thin film transistor is connected with the second signal line;
a second insulating layer, covering the thin film transistor and the second signal line; and
a discharge layer, located on a side of the second insulating layer away from the carrier substrate and connected with at least one of the first signal line and the second signal line.

2. The array substrate according to claim 1, wherein the first insulating layer is further provided with a second through hole exposing the first signal line, the second insulating layer is provided with a third through hole in communication with the second through hole, the discharge layer is connected with the first signal line through the second through hole and the third through hole, and the at least one through hole comprises a fourth through hole located in the second through hole.

3. The array substrate according to claim 1, wherein the first insulating layer is further provided with a fourth through hole exposing the first signal line;
the array substrate further comprises a transition conductive layer, wherein the transition conductive layer is located on a side of the first insulating layer away from the carrier substrate, and is connected with the first signal line through the fourth through hole; and
the second insulating layer is provided with a fifth through hole exposing the transition conductive layer, and the first discharge layer is connected with the transition conductive layer through the fifth through hole.

4. The array substrate according to claim 3, wherein the transition conductive layer and the second signal line are arranged in a same layer and of a same material.

5. The array substrate according to claim 1, wherein the second insulating layer is provided with a sixth through hole exposing the second signal line, and the discharge layer is connected with the second signal line through the sixth through hole.

6. The array substrate according to claim 1, wherein the discharge layer is located outside the display area.

7. The array substrate according to claim 1, further comprising a common electrode, wherein the common electrode and the discharge layer are arranged in a same layer and of a same material.

8. The array substrate according to claim 2, further comprising a common electrode, wherein the common electrode and the discharge layer are arranged in a same layer and of a same material.

9. The array substrate according to claim 1, wherein the second insulating layer is provided with a first insulating sub-layer and a second insulating sub-layer, the first insulating sub-layer covers the thin film transistor and the second signal line, the second insulating sub-layer is located at a side of the first insulating sub-layer away from the carrier substrate, and a material of the first insulating sub-layer is different from that of the second insulating sub-layer.

10. The array substrate according to claim 2, wherein the second insulating layer is provided with a first insulating sub-layer and a second insulating sub-layer, the first insulating sub-layer covers the thin film transistor and the second signal line, the second insulating sub-layer is located at a side of the first insulating sub-layer away from the carrier substrate, and a material of the first insulating sub-layer is different from that of the second insulating sub-layer.

11. A method for preparing an array substrate, comprising:
forming a first signal line, a first insulating layer, a second signal line, and a thin film transistor on a surface of a carrier substrate; wherein the carrier substrate is provided with a display area and a non-display area; the first signal line is located in the non-display area; the first insulating layer covers at least the first signal line, and is provided with a first through hole exposing the first signal line; the second signal line is located on a side of the first insulating layer away from the carrier substrate and connected with the first signal line through the first through hole; and the thin film transistor is located in the display area, wherein a gate of the thin film transistor is connected with the second signal line;
forming a second insulating layer; wherein the second insulating layer covers the thin film transistor and the second signal line; and
forming a discharge layer located on a side of the second insulating layer away from the carrier substrate; wherein the discharge layer is connected with at least one of the first signal line and the second signal line.

12. A display panel, comprising a pairing substrate and an array substrate; wherein the array substrate comprises:
a carrier substrate, provided with a display area and a non-display area;
a first signal line, located in the non-display area;
a first insulating layer, covering at least the first signal line, and providing with a first through hole exposing the first signal line;
a second signal line, located on a side of the first insulating layer away from the carrier substrate and connected with the first signal line through the first through hole;
a thin film transistor, located in the display area, wherein a gate of the thin film transistor is connected with the second signal line;
a second insulating layer, covering the thin film transistor and the second signal line; and
a discharge layer, located on a side of the second insulating layer away from the carrier substrate and connected with at least one of the first signal line and the second signal line; and
wherein the pairing substrate is arranged opposite to the array substrate.

13. The display panel according to claim 12, wherein the first insulating layer is further provided with a second through hole exposing the first signal line, the second insulating layer is provided with a third through hole in communication with the second through hole, the discharge layer is connected with the first signal line through the second through hole and the third through hole, and the at least one through hole comprises a fourth through hole located in the second through hole.

14. The display panel according to claim 12, wherein the first insulating layer is further provided with a fourth through hole exposing the first signal line;
the array substrate further comprises a transition conductive layer, wherein the transition conductive layer is located on a side of the first insulating layer away from the carrier substrate, and is connected with the first signal line through the fourth through hole; and
the second insulating layer is provided with a fifth through hole exposing the transition conductive layer, and the first discharge layer is connected with the transition conductive layer through the fifth through hole.

15. The display panel according to claim 14, wherein the transition conductive layer and the second signal line are arranged in a same layer and of a same material.

16. The display panel according to claim 12, wherein the second insulating layer is provided with a sixth through hole exposing the second signal line, and the discharge layer is connected with the second signal line through the sixth through hole.

17. The display panel according to claim 12, wherein the discharge layer is located outside the display area.

18. The display panel according to claim 12, further comprising a common electrode, wherein the common electrode and the discharge layer are arranged in a same layer and of a same material.

19. The display panel according to claim 12, wherein the second insulating layer is provided with a first insulating sub-layer and a second insulating sub-layer, the first insulating sub-layer covers the thin film transistor and the second signal line, the second insulating sub-layer is located at a side of the first insulating sub-layer away from the carrier substrate, and a material of the first insulating sub-layer is different from that of the second insulating sub-layer.

20. The display panel according to claim 13, wherein the second insulating layer is provided with a first insulating sub-layer and a second insulating sub-layer, the first insulating sub-layer covers the thin film transistor and the second signal line, the second insulating sub-layer is located at a side of the first insulating sub-layer away from the carrier substrate, and a material of the first insulating sub-layer is different from that of the second insulating sub-layer.
